(19) United States
(12) Patent Application Publication
(10) Pub. No.: US 2011/0067233 A1
(43) Pub. Date: Mar. 24, 2011

(54) Method of fabricating printed circuit board

(75) Inventors: Seon Ha Kang, Cheongju (KR); Myung Sam Kang, Hwaseong (KR); Mi Sun Hwang, Suwon (KR); Kil Yong Yun, Suwon (KR); Min Jung Cho, Incheon (KR); Gil Yong Shin, Jeonju (KR); Ok Tae Kim, Suwon (KR)

(73) Assignee: SAMSUNG ELECTRO-MECHANICS CO., LTD., Suwon (KR)

(21) Appl. No.: 12/654,669

(22) Filed: Dec. 29, 2009

(30) Foreign Application Priority Data
Sep. 18, 2009 (KR) 10-2009-0088564

(51) Int. Cl. H05K 3/10

(52) U.S. Cl. 29/846

(57) ABSTRACT

A method of fabricating a printed circuit board, the method including: providing an insulating base body having a first surface on which a first circuit pattern is formed, and a second surface opposite to the first surface; pressing the first surface of the insulating base body onto at least one surface of an insulating layer such that the first circuit pattern is embedded in the insulating layer; forming a resist having a desired pattern on the second surface of the insulating base body; forming a trench by performing a plasma treatment on the second surface of the insulating base body on which the resist is formed; and forming a second circuit pattern by filling the trench with a conductive material. Accordingly, the conductive patterns can be formed using a simple process, thereby enhancing a process rate and productivity.

### CROSS-REFERENCE TO RELATED APPLICATIONS

This application claims the priority of Korean Patent Application No. 10-2009-0088564 filed on Sep. 18, 2009, in the Korean Intellectual Property Office, the disclosure of which is incorporated herein by reference.

### BACKGROUND OF THE INVENTION

1. Field of the Invention

The present invention relates to a method of fabricating a printed circuit board, and more particularly, to a method of fabricating a printed circuit board capable of forming a conductive pattern for circuit-pattern formation by using a simple process, thereby enhancing a process rate and productivity.

2. Description of the Related Art

The recent development within the electronics industry has rapidly increased the demand for smaller electronic components with greater functionality.

To cope with such demand, printed circuit boards have also been required to have high density circuit patterns. In this regard, various processes for implementing fine circuit patterns have been designed and are in use.

Representative processes for implementing fine circuit patterns include a semi-additive process (SAP) and an embedded process. The embedded process is associated with embedding a circuit in an insulating material. Since the embedded process achieves enhanced product flatness and rigidity as well as causing less damage to circuits, the embedded process is considered to be more suitable for fine circuits than SAP.

The embedded process may be performed using a variety of approaches. For example, a circuit formation method adopting a trench processing technique processes a circuit in an insulating material using lasers and performs plating thereupon, unlike an existing circuit formation method depending on the resolution of a dry film. However, this circuit formation method, adopting trench processing, needs to overcome the limitations of degraded circuit quality and low productivity resulting from the laser process for circuit configuration.

A method of forming a printed circuit board using a trench circuit technique according to the related art includes forming trench circuits and via holes using a laser drill in order to form inner-layer patterns and form outer-layer patterns. Subsequently, the via holes and the circuits formed by lasers are subjected to a de-smear process to remove smears, and then to a plating process. Thereafter, a resultant product is subjected to a physical planarization process using a polishing process, and is then etched to thereby remove an uneven circuit-pattern surface layer from the final surface.

A circuit completed in the above-described manner is impregnated into an insulating material, and thus becomes an embedded-type circuit. Since a trench circuit technique, which is currently in use, forms the entire circuit using lasers, productivity may be impaired and circuit quality is affected significantly by a laser processing ability. Therefore, there is great need for the development of laser processing techniques capable of overcoming the above limitations.

### SUMMARY OF THE INVENTION

An aspect of the present invention provides a method of fabricating a printed circuit board, capable of simply forming a conductive pattern for circuit-pattern formation, and thus enhancing a process rate and productivity.

According to an aspect of the present invention, there is provided a method of fabricating a printed circuit board, the method including: providing an insulating base body having a first surface on which a first circuit pattern is formed, and a second surface opposite to the first surface; pressing the first surface of the insulating base body onto at least one surface of an insulating layer such that the first circuit pattern is embedded in the insulating layer; forming a resist having a desired pattern on the second surface of the insulating base body; forming a trench by performing a plasma treatment on the second surface of the insulating base body on which the resist is formed; and forming a second circuit pattern by filling the trench with a conductive material.

The plasma treatment may be performed for ten minutes to sixty minutes.

The insulating base body may include a plurality of insulating base bodies, and the plasma treatment may be collectively performed on the plurality of insulating base bodies in a chamber.

The method may further include forming a via hole in the insulating base body, the via hole exposing the first circuit pattern.

The via hole may be formed by laser etching.

A via electrode may be formed in the via hole.

The insulating base body may include a plurality of insulating base bodies, and the pressing of the first surface may include pressing first surfaces of the insulating base bodies onto both surfaces of insulating layer, respectively.

The insulating base body may include polyimide.

The trench may be spaced apart from the first circuit pattern at a predetermined distance.

The resist may be removed by the plasma treatment.

The second circuit pattern and the via electrode may be formed by using at least one of electroless plating and electrolytic plating.

The method may further include performing a surface planarization process on the second circuit pattern and the via electrode.

The method may further include performing a surface etching process on the second circuit pattern and the via electrode.

The resist may be formed using a dry film.

According to another aspect of the present invention, there is provided a method of fabricating a printed circuit board, the method including: forming a resist having a desired pattern on at least one surface of an insulating base body; forming a trench by performing a plasma treatment on the insulating base body on which the resist is formed; and forming a circuit pattern in the trench.

The plasma treatment may be performed for ten minutes to sixty minutes.

The insulating base body may include a plurality of insulating base bodies, and the plasma treatment may be performed collectively on the plurality of insulating base bodies in a chamber.

The method may further include forming a via hole in the insulating base body, the via hole exposing the circuit pattern.

The via hole may be formed by laser etching.

A via electrode may be formed in the via hole.

The trench may be spaced apart from the circuit pattern at a predetermined distance.

The resist may be removed by the plasma treatment.

The circuit pattern and the via electrode may be formed by using at least one of electroless plating and electrolytic plating.

### BRIEF DESCRIPTION OF THE DRAWINGS

The above and other aspects, features and other advantages of the present invention will be more clearly understood from the following detailed description taken in conjunction with the accompanying drawings, in which:

FIGS. 1A through 1K are schematic cross-sectional views illustrating a process of fabricating a printed circuit board according to an exemplary embodiment of the present invention.

### DETAILED DESCRIPTION OF THE PREFERRED EMBODIMENT

Exemplary embodiments of the present invention will now be described in detail with reference to the accompanying drawings.

The invention may, however, be embodied in many different forms and should not be construed as being limited to the embodiments set forth herein. Rather, these embodiments are provided so that this disclosure will be thorough and complete, and will fully convey the scope of the invention to those skilled in the art. In the drawings, the thicknesses of layers and regions are exaggerated for clarity. Like reference numerals in the drawings denote like elements.

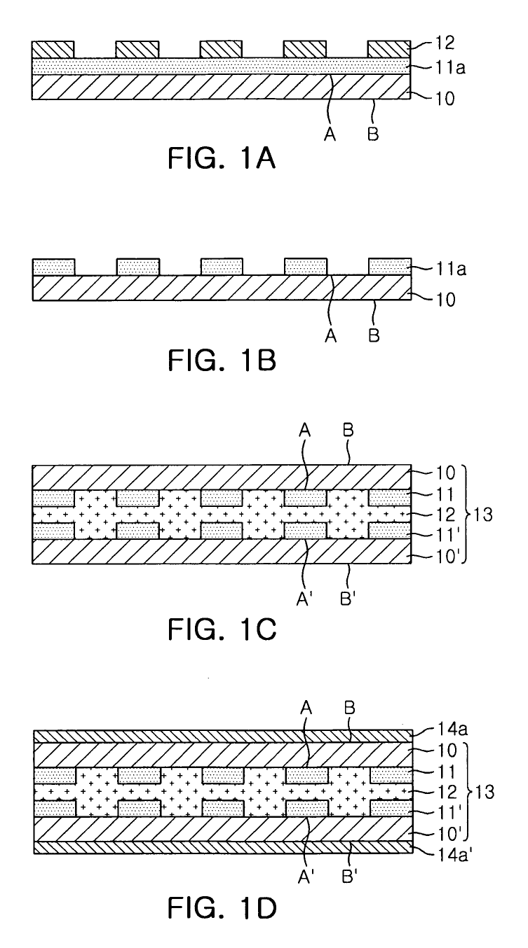

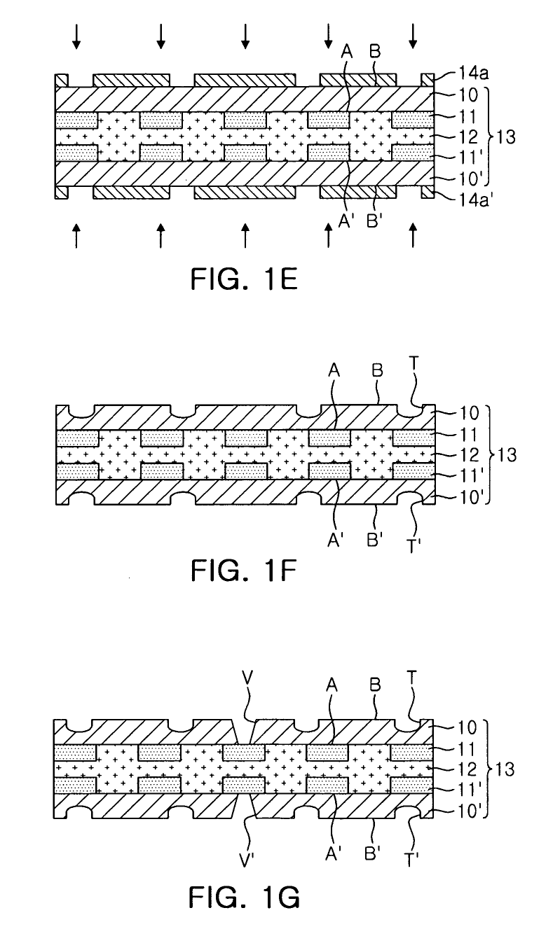

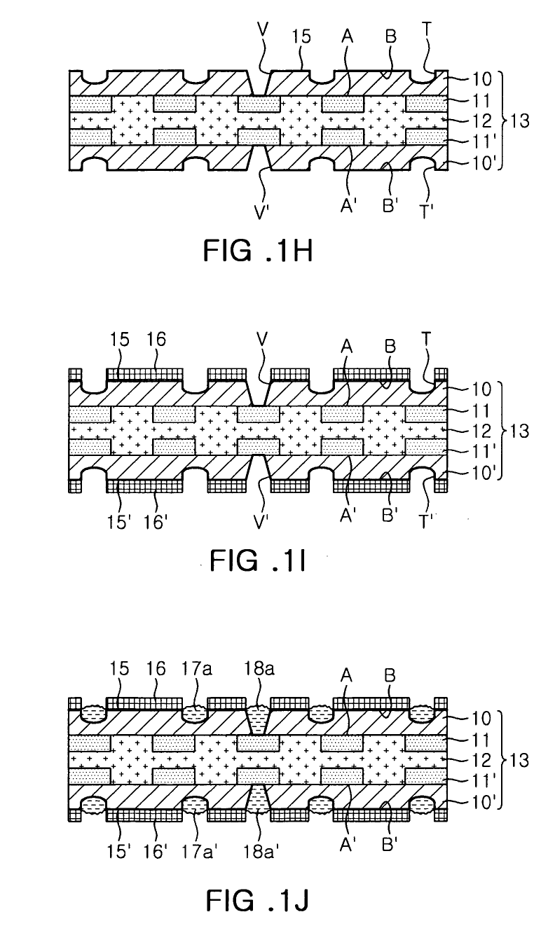

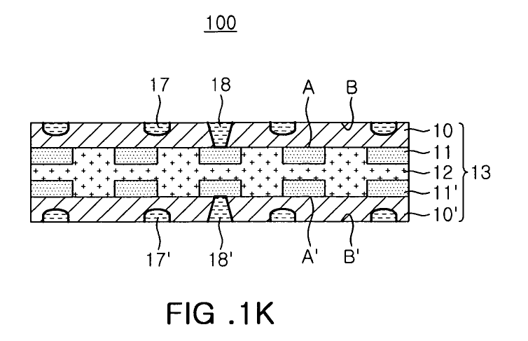

A process for fabricating a printed circuit board, according to an exemplary embodiment of the present invention, will now be described with reference to FIGS. 1A through 1K.

Referring to FIGS. 1A and 1B, a copper layer 11a and a dry film (not shown) are sequentially stacked on a first surface A of an insulating base body 10. A resist 12 having a desired pattern is then formed by performing light-exposure and development on the dry film. To form the resist 12, a dry film may be used as described above; however, a photosensitive resist, used in a typical photolithography process, may be used. The insulating base body 10 may be formed of a general polymer resin, and may contain a polyimide-based resin.

Thereafter, the copper layer 11a is etched by using the resist 12 to thereby form a first circuit pattern 11 on the first surface A of the insulating base body 10.

As shown in FIG. 1C, an insulating layer 12 is then provided. Respective first surfaces A and A′ of two insulating base bodies 10 and 10′ are pressed onto the insulating layer 12 such that first circuit patterns 11 and 11′ are embedded in the top and bottom surfaces of the insulating layer 12, respectively. In such a manner, an insulating base stack 13 is formed.

Thereafter, as shown in FIGS. 1D through 1F, dry films 14a and 14a′ are formed on the top and bottom surfaces of the insulating base stack 13, respectively, and are subjected to light-exposure and development to thereby form resists 14 and 14′ having desired patterns.

Subsequently, a plasma treatment is performed on the insulating base stack 13 in a chamber as indicated by arrows, thereby forming trenches T and T′ in the insulating base stack 13.

Here, the trenches T are spaced apart from the first circuit pattern 11 at a predetermined distance, and the trenches T′ are also spaced apart from the first circuit patterns 11′ at a predetermined distance.

Here, the plasma treatment may be performed for ten to sixty minutes, and may be performed preferably for approximately twenty minutes to forty minutes.

Moreover, a plurality of insulating base stacks 13 may be collectively subjected to the plasma treatment within a chamber. At this time, the resist 14 may be removed by this plasma treatment.

Since trenches for circuit-pattern formation in a printed circuit board are mass-produced within a short period of time, the process rate and productivity can be enhanced.

Subsequently, as shown in FIG. 1G, laser etching is performed to thereby form via holes V and V′ in the top and bottom surfaces of the insulating base stack 13, respectively. The via holes V and V′ expose the first circuit patterns 11 and 11′ in order to achieve interlayer connections.

Thereafter, as shown in FIG. 1H, electroless plating is performed to thereby form an electroless plating layer 15 on the insulating base body 10.

Then, as shown in FIG. 1I, resists 16 and 16′ are formed on a resultant structure, excluding the trenches T and T′ for forming circuit patterns.

Subsequently, as shown in FIG. 1J, electrolytic plating is performed thereon to form respective via electrodes 18a and 18a′ in the via holes V and V′ while forming respective second circuit patterns 17a and 17a′ in the trenches T and T′ for forming circuit patterns.

Then, the second circuit patterns 17a and 17a′ and the via electrodes 18a and 18a′ having uneven surfaces are subjected to a surface planarization process. Thereafter, the surfaces of the second circuit patterns 17a and 17a′ and the via electrodes 18a and 18a′ are etched to thereby form conductive patterns 17, 17′, 18 and 18′ for circuit pattern formation as shown in FIG. 1K. In the above manner, a printed circuit board 100 according to an exemplary embodiment of the present invention is completed.

Even if the exemplary embodiment of the present invention embeds circuit patterns formed on insulating base bodies into an insulating layer, the present invention is not limited to the description and may also be applicable to the case in which the circuit patterns are formed on the insulating layer.

As set forth above, according to exemplary embodiments of the invention, there is provided a method of fabricating a printed circuit board, capable of enhancing a process rate and productivity by forming conductive patterns for circuit patterns using a simple process.

Moreover, when the conductive patterns for circuit patterns are formed, a plasma treatment substitutes for a laser process, thereby achieving a reduction in process costs.

While the present invention has been shown and described in connection with the exemplary embodiments, it will be apparent to those skilled in the art that modifications and variations can be made without departing from the spirit and scope of the invention as defined by the appended claims.

What is claimed is:

1. A method of fabricating a printed circuit board, the method comprising:
providing an insulating base body having a first surface on which a first circuit pattern is formed, and a second surface opposite to the first surface;
pressing the first surface of the insulating base body onto at least one surface of an insulating layer such that the first circuit pattern is embedded in the insulating layer;
forming a resist having a desired pattern on the second surface of the insulating base body;
forming a trench by performing a plasma treatment on the second surface of the insulating base body on which the resist is formed; and
forming a second circuit pattern by filling the trench with a conductive material.

2. The method of claim 1, wherein the plasma treatment is performed for ten minutes to sixty minutes.

3. The method of claim 1, wherein the insulating base body comprises a plurality of insulating base bodies, and the plasma treatment is collectively performed on the plurality of insulating base bodies in a chamber.

4. The method of claim 1, further comprising forming a via hole in the insulating base body, the via hole exposing the first circuit pattern.

5. The method of claim 4, wherein the via hole is formed by laser etching.

6. The method of claim 4, wherein a via electrode is formed in the via hole.

7. The method of claim 1, wherein the insulating base body comprises a plurality of insulating base bodies, and the pressing of the first surface comprises pressing first surfaces of the insulating base bodies onto both surfaces of insulating layer, respectively.

8. The method of claim 1, wherein the insulating base body includes polyimide.

9. The method of claim 1, wherein the trench is spaced apart from the first circuit pattern at a predetermined distance.

10. The method of claim 1, wherein the resist is removed by the plasma treatment.

11. The method of claim 6, wherein the second circuit pattern and the via electrode are formed by using at least one of electroless plating and electrolytic plating.

12. The method of claim 6, further comprising performing a surface planarization process on the second circuit pattern and the via electrode.

13. The method of claim 6, further comprising performing a surface etching process on the second circuit pattern and the via electrode.

14. The method of claim 1, wherein the resist is formed using a dry film.

15. A method of fabricating a printed circuit board, the method comprising:
forming a resist having a desired pattern on at least one surface of an insulating base body;
forming a trench by performing a plasma treatment on the insulating base body on which the resist is formed; and
forming a circuit pattern in the trench.

16. The method of claim 15, wherein the plasma treatment is performed for ten minutes to sixty minutes.

17. The method of claim 15, wherein the insulating base body comprises a plurality of insulating base bodies, and the plasma treatment is performed collectively on the plurality of insulating base bodies in a chamber.

18. The method of claim 15, further comprising forming a via hole in the insulating base body, the via hole exposing the circuit pattern.

19. The method of claim 18, wherein the via hole is formed by laser etching.

20. The method of claim 18, wherein a via electrode is formed in the via hole.

21. The method of claim 15, wherein the trench is spaced apart from the circuit pattern at a predetermined distance.

22. The method of claim 15, wherein the resist is removed by the plasma treatment.

23. The method of claim 18, wherein the circuit pattern and the via electrode are formed by using at least one of electroless plating and electrolytic plating.
